(19) United States
(12) Patent Application Publication
(10) Pub. No.: US 2026/0227467 A1
(43) Pub. Date: Aug. 6, 2026

(54) METHOD AND APPARATUS FOR POLARIZING NUCLEAR SPINS AND STORAGE MEDIUM STORING PROGRAM THEREFOR

(71) Applicants: Institute of Science Tokyo, Tokyo (JP); Korea Institute of Science and Technology, Seoul (KR)

(72) Inventors: Keigo ARAI, Tokyo (JP); Eikichi KIMURA, Tokyo (JP); Junghyun LEE, Seoul (KR); Jiwon JEON, Seoul (KR)

(73) Assignees: Institute of Science Tokyo, Tokyo (JP); Korea Institute of Science and Technology, Seoul (KR)

(21) Appl. No.: 19/389,631

(22) Filed: Nov. 14, 2025

(30) Foreign Application Priority Data
Jan. 31, 2025 (JP) 2025-015640

(51) Int. Cl. G01R 33/26

(52) U.S. Cl. CPC G01R 33/26

(57) ABSTRACT

A method for polarizing nuclear spins includes a process to apply a static magnetic field to NV centers, a process to irradiate the NV centers with a first microwave having a first microwave wavelength to transition energy levels mₛ of electron spins of the NV centers of which energy levels mₗ of nuclear spins are one of mₗ=1 or −1 from mₛ=0 to mₛ=−1, and a process to irradiate the NV centers with a second microwave having a second microwave wavelength different from the first microwave wavelength to transition the energy levels mₛ of electron spins of the NV centers of which the energy levels mₗ of the nuclear spins are the other of mₗ=1 or −1 from mₛ=0 to mₛ=−1 when a microwave irradiation waiting period determined depending on the period of state mixing of polarization of the nuclear spins has elapsed since the irradiation with the first microwave.

### FIELD

The present disclosure relates to a method and an apparatus for polarizing nuclear spins and a storage medium storing a program therefor.

### BACKGROUND

Nitrogen-vacancy (NV) centers, in each of which a pair of carbon atoms forming diamond is substituted with a nitrogen atom and a vacancy and a quantum system with a spin number of 1 is formed by a pair of electron spins, are known to form a quantum many-body system by bonding with surrounding NV centers through the magnetic dipole interaction of electrons. Performing appropriate quantum manipulation on the electron spins of NV centers forming a quantum many-body system enables an entangled state to be formed and quantum computing with quantum supremacy to be achieved by using the formed entangled state. The quantum manipulation of electron spins for forming an entangled state is performed by irradiating NV centers with microwaves.

To use NV centers in quantum computing, it is desirable to achieve a fidelity of 99.0% or more, which is a measure of the closeness between the state expected to be achieved by quantum manipulation of electron spins and the state actually achieved by quantum manipulation of electron spins. Non-Patent Document 1 discloses that a fidelity of 96.0% has been achieved; however, to achieve quantum computing with NV centers, it is desirable to further improve the fidelity to 99.0% or more.

There are known techniques for polarizing nitrogen-14 nuclear spins (hereinafter also referred to as “nitrogen nuclear spins”) in NV centers (e.g., see Non-Patent Documents 2 and 3). The techniques described in Non-Patent Documents 2 and 3 enable polarizing nitrogen-14 nuclear spins when the direction of nitrogen-vacancy alignment in NV centers is parallel to that of an applied magnetic field.

### CITATION LIST

### Non-Patent Document

Non-Patent Document 1: “High-Fidelity Electron Spin Gates in a Scalable Diamond Quantum Register” T. Joas et al., arXiv: 2024.04199 (2024)
Non-Patent Document 2: “Dynamic 14N nuclear spin polarization in nitrogen-vacancy centers in diamond” Laima Busaite et al., PHYSICAL REVIEW B 102, 224101 (2020)
Non-Patent Document 3: “Polarizing the electronic and nuclear spin of the NV-center in diamond in arbitrary magnetic fields: analysis of the optical pumping process” Tanmoy Chakraborty et al., New Journal of Physics, 19, 073030 (2017)

### SUMMARY

The present inventors have found that polarizing nitrogen nuclear spins in NV centers is effective in improving fidelity. The techniques described in Non-Patent Documents 2 and 3 enable polarizing nitrogen nuclear spins when the direction of nitrogen-vacancy alignment is parallel to that of an applied magnetic field; however, in NV centers used in quantum computing, the direction of nitrogen-vacancy alignment is not uniform, so that state mixing occurs between the states of nuclear spins. The techniques described in Non-Patent Documents 2 and 3 cause state mixing between the states of nitrogen nuclear spins of NV centers of which the direction of nitrogen-vacancy alignment is not uniform, which may reduce the fidelity of polarization of nitrogen nuclear spins and that of quantum manipulation of electron spins.

The present disclosure aims to solve such a problem and to provide a method for polarizing nuclear spins that enables improving the fidelity of quantum manipulation of electron spins.

A method for polarizing nuclear spins of the present disclosure includes a static magnetic field application process to apply a static magnetic field to NV centers, a first microwave irradiation process to irradiate the NV centers with a microwave having a first microwave wavelength to transition energy levels mₛ of electron spins of the NV centers of which energy levels mₗ of nuclear spins are one of mₗ=1 or −1 from mₛ=0 to mₛ=−1, and a second microwave irradiation process to irradiate the NV centers with a microwave having a second microwave wavelength different from the first microwave wavelength to transition the energy levels mₛ of electron spins of the NV centers of which the energy levels mₗ of the nuclear spins are the other of m=1 or −1 from mₛ=0 to mₛ=−1 when a microwave irradiation waiting period determined depending on the period of state mixing of polarization of the nuclear spins has elapsed since execution of the first microwave irradiation process.

In the method of the present disclosure, the first microwave irradiation process preferably causes the energy levels mₛ of the electron spins of the NV centers of which the energy levels mₗ of the nuclear spins are mₗ=1 to transition from mₛ=0 to mₛ=−1, and the second microwave irradiation process preferably causes the energy levels mₛ of the electron spins of the NV centers of which the energy levels mₗ of the nuclear spins are mₗ=−1 to transition from mₛ=0 to mₛ=−1.

In the method of the present disclosure, the first microwave irradiation process preferably causes the energy levels mₛ of the electron spins of the NV centers of which the energy levels mₗ of the nuclear spins are mₗ=−1 to transition from mₛ=0 to mₛ=−1, and the second microwave irradiation process preferably causes the energy levels mₛ of the electron spins of the NV centers of which the energy levels mₗ of the nuclear spins are mₗ=1 to transition from mₛ=0 to mₛ=−1.

The method of the present disclosure preferably further includes a first radio wave irradiation process to irradiate the NV centers subjected to the first microwave irradiation process with a radio wave having a first radio wave wavelength to transition the energy levels mₗ of the nuclear spins to mₗ=0 with the energy levels mₛ of the electron spins transitioned to mₛ=−1, and a first laser light irradiation process to irradiate the NV centers subjected to the first radio wave irradiation process with laser light having a laser light wavelength to transition the energy levels mₛ of the electron spins from mₛ=−1 to mₛ=0 with the energy levels mₗ of the nuclear spins transitioned to mₗ=0.

The method of the present disclosure preferably further includes a second radio wave irradiation process to irradiate the NV centers subjected to the second microwave irradiation process with a radio wave having a second radio wave wavelength different from the first radio wave wavelength to transition the energy levels mₗ of the nuclear spins to mₗ=0 with the energy levels mₛ of the electron spins transitioned to mₛ=−1, and a second laser light irradiation process to irradiate the NV centers subjected to the second radio wave irradiation process with the laser light to transition the energy levels mₛ of the electron spins from mₛ=−1 to mₛ=0 with the energy levels mₗ of the nuclear spins transitioned to mₗ=0.

The method of the present disclosure preferably further includes an initialization process to irradiate the NV centers with the laser light to transition the energy levels mₛ of the electron spins of the NV centers to mₛ=0 before the first microwave irradiation process.

The method of the present disclosure preferably further includes a waiting process to wait to execute the first laser light irradiation process for a laser light irradiation waiting period determined depending on the microwave irradiation waiting period, between the first radio wave irradiation process and the first laser light irradiation process.

In the method of the present disclosure, the laser light irradiation waiting period is preferably on the order of microseconds.

In the method of the present disclosure, the laser light irradiation waiting period is preferably longer than 10 μs.

A non-transitory storage medium of the present disclosure stores a program for polarizing nuclear spins. The program causes a computer to execute a process including a static magnetic field application process to apply a static magnetic field to NV centers, a first microwave irradiation process to irradiate the NV centers with a microwave having a first microwave wavelength to transition energy levels mₛ of electron spins of the NV centers of which energy levels mₗ of nuclear spins are one of mₗ=1 or −1 from mₛ=0 to mₛ=−1, and a second microwave irradiation process to irradiate the NV centers with a microwave having a second microwave wavelength different from the first microwave wavelength to transition the energy levels mₛ of electron spins of the NV centers of which the energy levels mₗ of the nuclear spins are the other of mₗ=1 or −1 from mₛ=0 to mₛ=−1 when a microwave irradiation waiting period determined depending on the period of state mixing of polarization of the nuclear spins has elapsed since execution of the first microwave irradiation process.

An apparatus for polarizing nuclear spins of the present disclosure includes a diamond with NV centers formed, a static magnetic field application device configured to apply a static magnetic field to the NV centers, a wave irradiation device configured to irradiate the NV centers with radio waves, and a controller configured to control the static magnetic field application device and the wave irradiation device. The controller is configured to execute a static magnetic field application process for the static magnetic field application device to apply the static magnetic field to the NV centers, a first microwave irradiation process for the wave irradiation device to irradiate the NV centers with a microwave having a first microwave wavelength to transition energy levels mₛ of electron spins of the NV centers of which energy levels mₗ of nuclear spins are one of mₗ=1 or −1 from mₛ=0 to mₛ=−1, and a second microwave irradiation process for the wave irradiation device to irradiate the NV centers with a microwave having a second microwave wavelength different from the first microwave wavelength to transition the energy levels mₛ of electron spins of the NV centers of which the energy levels mₗ of the nuclear spins are the other of mₗ=1 or −1 from mₛ=0 to mₛ=−1 when a microwave irradiation waiting period determined depending on the period of state mixing of polarization of the nuclear spins has elapsed since execution of the first microwave irradiation process.

The method of the present disclosure enables improving the fidelity of quantum manipulation of electron spins.

### BRIEF DESCRIPTION OF DRAWINGS

FIG. 1 is a block diagram of an apparatus for polarizing nuclear spins of an embodiment;

FIG. 2 is a flowchart showing a process for polarizing nuclear spins executed by a processing unit shown in FIG. 1;

FIG. 3 is a timing chart of the process for polarizing nuclear spins shown in FIG. 2;

FIG. 4A shows how the fidelity of quantum manipulation of nuclear spins depends on the direction of an applied static magnetic field in a method for polarizing nuclear spins of a comparative example; and

FIG. 4B shows how the fidelity of quantum manipulation of nuclear spins depends on the direction of an applied static magnetic field in a method for polarizing nuclear spins of the embodiment.

### DESCRIPTION OF EMBODIMENTS

A method and an apparatus for polarizing nuclear spins of an embodiment and a storage medium storing a program therefor will now be described with reference to the attached drawings. However, note that the technical scope of the present invention is not limited to embodiments thereof and covers the invention described in the claims and equivalents thereof.

### (Overview of a Method for Polarizing Nuclear Spins of an Embodiment)

Based on the technology described in Non-Patent Document 1, the present inventors have identified the following three technical problems of further improving the fidelity of quantum manipulation of electron spins.
(1) Discrepancy between the directions of an applied magnetic field and nitrogen-vacancy alignment
(2) Crosstalk of microwaves with which NV centers are irradiated
(3) Presence of unpolarized nuclear spins

The discrepancy between the directions of an applied magnetic field and nitrogen-vacancy alignment contributes 12.5% to the improvement in the fidelity of quantum manipulation of electron spins. Although the discrepancy between the directions of an applied magnetic field and nitrogen-vacancy alignment can be resolved by forming diamond with NV centers of which the direction of nitrogen-vacancy alignment is uniform, forming such diamond is not easy.

Crosstalk of microwaves with which NV centers are irradiated contributes 25.0% to the improvement in the fidelity of quantum manipulation of electron spins. Crosstalk of microwaves with which NV centers are irradiated can be suppressed by lowering the Rabi frequency of the NV centers. However, since the lower limit of Rabi frequency is limited by coherence time, it is not easy to suppress crosstalk of microwaves with which NV centers are irradiated.

The presence of unpolarized nuclear spins contributes 56.3% to the improvement in the fidelity of quantum manipulation of electron spins. Although the presence of unpolarized nuclear spins can be reduced by polarizing the nuclear spins, the techniques described in Non-Patent Documents 2 and 3 may reduce the fidelity of polarization of nuclear spins and that of quantum manipulation of electron spins.

The present inventors have found that applying a static magnetic field causes periodic state mixing between the states of the nitrogen nuclear spins of NV centers.

The Hamiltonian H of the ground state ³A₂ is given by expression (1) below.

$$[ Expression 1 ]$$

$$H \text{?} = D \text{?} S \text{?} \text{?} + \text{?} B \cdot S \text{?} + Q \text{?} \text{?} \text{?} - \text{?} B \cdot I \text{?} + A \text{?} \text{?} ( S \text{?} \text{?} I \text{?} \text{?} + S \text{?} \text{?} I \text{?} \text{?} ) + A \text{?} S \text{?} \text{?} I \text{?} \text{?} \qquad ( 1 )$$

$$\text{?} \text{indicates text missing or illegible when filed}$$

D_{gs}=2π=2.87 GHz represents the zero-field splitting, γₑ=2π=28 GHz/T the electron gyromagnetic ratio, B=(Bₓ, B_{y}, B_{z}) the external magnetic field, and Q/2π=−4.945 MHz the nuclear quadrupole interaction of nitrogen-14 nuclear spins. γ_{N}/2π=0.307 MHz/T represents the nuclear gyromagnetic ratio, and A ⊥_{gs}/2π=−2.62 MHz and A//_{gs}/2π=−2.16 MHz represent the hyperfine interaction between electron and nuclear spins.

$$[ Expression 2 ]$$

$$S \text{?} = ( S \text{?} \text{?} , S \text{?} \text{?} , S \text{?} \text{?} ) \text{?} I \text{?} = ( I \text{?} \text{?} , I \text{?} \text{?} , I \text{?} \text{?} )$$

$$\text{?} \text{indicates text missing or illegible when filed}$$

denote the spin operators of spin 1 of electron and nuclear spins, respectively.

According to Fermi's golden rule, the transition probability W from an initial state |i> to a final state |f> of a system defined by Hamiltonian H is given by expression (2) below.

$$[ Expression 3 ]$$

$${W}_{i \to f} = \frac{2 π}{\text{?}} {\vert 〈 f \vert T \vert i 〉 \vert}^{2} δ ( {E}_{f} - {E}_{i} ) \qquad ( 2 )$$

$$\text{?} \text{indicates text missing or illegible when filed}$$

In expression (2),

$$[ Expression 4 ]$$

$$T = {T}^{( 1 )} + {T}^{( 2 )} + {T}^{( 3 )} + ... \qquad ( 3 )$$

$$〈 f \vert {T}^{( 1 )} \vert i 〉 = 〈 f \vert H \vert i 〉 \qquad ( 4 )$$

$$〈 f \vert {T}^{( 2 )} \vert i 〉 = {\sum }_{n} \frac{〈 f \vert H \vert n 〉 〈 n \vert H \vert i 〉}{{E}_{n} - {E}_{i}} \qquad ( 5 )$$

$$〈 f \vert {T}^{( 3 )} \vert i 〉 = {\sum }_{{n}_{1} , {n}_{2}} \frac{〈 f \vert H \vert {n}_{2} 〉 〈 {n}_{2} \vert H \vert {n}_{1} 〉 〈 {n}_{1} \vert H \vert i 〉}{( {E}_{{n}_{2}} - {E}_{i} ) ( {E}_{{n}_{1}} - {E}_{i} )} \qquad ( 6 )$$

$$⋮ \qquad ( 7 )$$

$$where$$

$$[ Expression 5 ]$$

$$\text{?} = 6.626 \times {10}^{- 34} / 2 π Js$$

$$\text{?} \text{indicates text missing or illegible when filed}$$

denotes the reduced Planck constant, δ(x) denotes the Dirac δ function, and Eₓ is the intrinsic energy of a state |x>. By calculating the first-order transition probability <f|T⁽¹⁾|i> to the nth-order transition probability <f|T⁽ⁿ⁾|i> in expression (2) one by one, the inventors have found that the third- and fourth-order transition probabilities <f|T⁽³⁾|i> and <f|T⁽⁴⁾|i> account for more than 99% of the total transition probability and are dominant. Extracting the third- and fourth-order transition probabilities <f|T⁽³⁾|i> and <f|T⁽⁴⁾|i>, which account for more than 99% of the total transition probability, and using γ_{N}B_{z}<<Q and A//_{gs}, γₑB_{z}<<D_{gs} lead to expression (8) below.

$$[ Expression 6 ]$$

$$T \text{?} \text{?} \frac{2 \text{?}}{\text{?}} \vert \frac{2 A \text{?} B \text{?}}{D \text{?} Q \text{?}} + \frac{2 A \text{?} B}{D \text{?} Q} \vert \text{?} \text{?} ( 2 \text{?} B \text{?} ) \qquad ( 8 )$$

$$\text{?} \text{indicates text missing or illegible when filed}$$

With the definition in expressions (9) and (10) below, Hamiltonian H₂, which is a system consisting of two states |0, −1> and |0, 1>, is given by expression (11).

$$[ Expression 7 ]$$

$$Ω = \frac{2 {A}_{⊥}^{2} {\text{?}}_{N}^{2} {B}^{2} \text{?}}{D \text{?} Q} + \frac{2 A \text{?} {\text{?}}_{N} \text{?} {B}^{2} \text{?}}{D \text{?} Q} \qquad ( 9 )$$

$$δ = \text{?} \text{?} B \text{?} \qquad ( 10 )$$

$${H}_{2} = Ω ( \begin{matrix}0 & 1 \\ 1 & 0\end{matrix} ) + δ ( \begin{matrix}1 & 0 \\ 0 & - 1\end{matrix} ) \qquad ( 11 )$$

$$\text{?} \text{indicates text missing or illegible when filed}$$

Calculation of the probability of existence of |0, 1> in |ψ(t)> obtained by substituting the Hamiltonian H₂ of expression (11) into the Schrödinger equation of expression (12) and solving the equation under the initial condition given by expression (13) leads to expression (14).

$$[ Expression 8 ]$$

$$\text{?} \text{?} \frac{d}{dt} \vert \text{?} \text{?} = {H}_{2} \vert \text{?} \text{?} \qquad ( 12 )$$

$$\vert \text{?} ( 0 ) 〉 = \vert 0 , - 1 〉 \qquad ( 13 )$$

$${\vert ( 0 , 1 \vert \text{?} ( t ) 〉 \vert}^{2} = A + B cos ( 2 \sqrt{{Ω}^{2} + {δ}^{2} t} ) \qquad ( 14 )$$

$$\text{?} \text{indicates text missing or illegible when filed}$$

In expression (14), A and B are constants. From expression (14), the period T of the mixed state of the periodically changing nitrogen nuclear spins of NV centers is given by expression (15) below.

$$[ Expression 9 ]$$

$$T = \frac{π}{\sqrt{{Ω}^{2} + {δ}^{2}}} \qquad ( 15 )$$

The present inventors have further found that the fidelity of polarization of nitrogen nuclear spins is improved by executing a second microwave irradiation process when a microwave irradiation waiting period determined depending on the found period of state mixing has elapsed since a first microwave irradiation process. The present disclosure improves the fidelity of polarization of nitrogen nuclear spins and that of quantum manipulation of electron spins by executing a second microwave irradiation process when a microwave irradiation waiting period determined depending on the period of state mixing has elapsed since a first microwave irradiation process.

### (Configuration and Function of an Apparatus for Polarizing Nuclear Spins of an Embodiment)

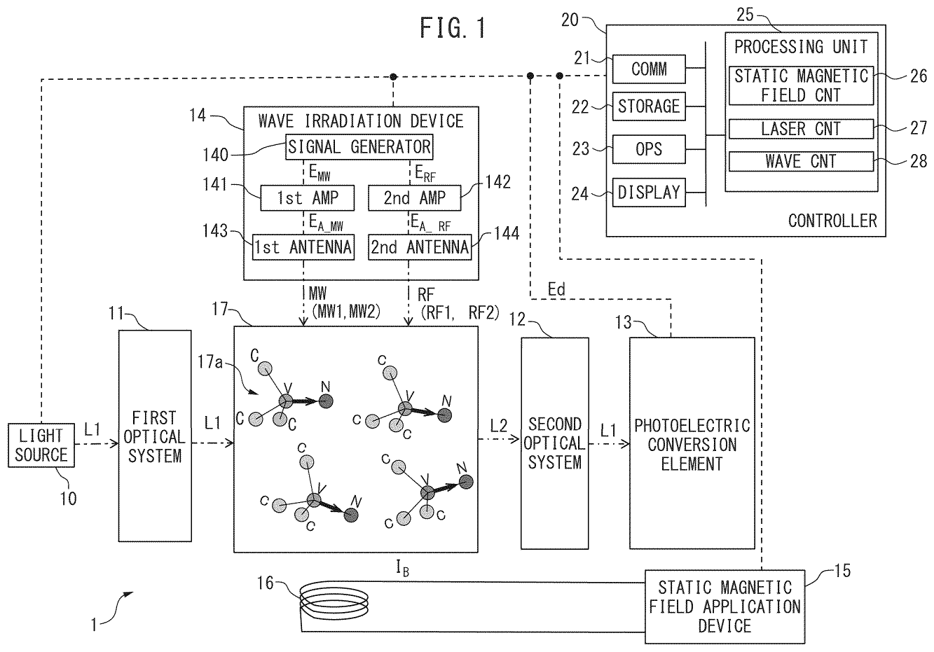

FIG. 1 is a block diagram of an apparatus for polarizing nuclear spins of an embodiment. In FIG. 1, electrical signal lines are indicated by dashed lines, optical paths by dash-dot lines, and radio waves by dash-dot-dot lines.

The apparatus 1 for polarizing nuclear spins includes a light source 10, a first optical system 11, a second optical system 12, a photoelectric conversion element 13, a wave irradiation device 14, a static magnetic field application device 15, a coil 16, a diamond 17, and a controller 20. The apparatus 1 irradiates NV centers 17a with a microwave again after a predetermined microwave irradiation period has elapsed since irradiation with a microwave, thereby enabling the electron spins of nitrogen (N) included in the NV centers 17a to transition from mₛ=0 to mₛ=−1 with the nuclear spins polarized.

The light source 10 is a green light-emitting element such as an InGaN semiconductor laser, and outputs laser light L1 having a laser light wavelength to the first optical system 11. The laser light wavelength is, for example, 532 nm, and the laser light L1 is, for example, green light. The laser light L1 emitted from the light source 10 transitions the energy levels mₛ of electron spins of the NV centers 17a included in the diamond 17 from mₛ=−1 to mₛ=0. The first optical system 11 is composed of optical elements such as an acousto-optical modulator and an objective lens, and condenses the laser light L1 emitted from the light source 10 to irradiate the diamond 17 with the condensed light. The second optical system 12 is composed of optical elements such as a pinhole disposed at a conjugate point of the diamond 17, and condenses red light L2 having a wavelength of 600 nm to 800 nm emitted from the diamond 17 to emit the condensed light to the photoelectric conversion element 13. The photoelectric conversion element 13 includes a photodiode, an amplifier circuit, and the like, generates an electrical signal depending on the amount of red light L2 incident from the second optical system 12, and outputs the generated electrical signal to the controller 20.

The wave irradiation device 14 includes a signal generator 140, a first amplifier 141, a second amplifier 142, a first antenna 143, and a second antenna 144. The wave irradiation device 14 generates microwaves MW and radio waves RF, and irradiates the NV centers 17a with the generated microwaves MW and radio waves RF. The signal generator 140 is a signal generating device capable of generating a periodic signal having an arbitrary frequency and waveform, such as a function generator or an arbitrary waveform generator. The signal generator 140 generates a microwave signal E_{MW} having a frequency of 300 MHz to 300 GHz, i.e., a wavelength of 1 mm to 1 m, and outputs the generated microwave signal E_{MW} to the first amplifier 141. The signal generator 140 also generates a radio wave signal ERF having a frequency of 30 Hz to 300 MHz, i.e., a wavelength of 1 m to 10,000 km, and outputs the generated radio wave signal ERF to the second amplifier 142.

Each of the first and second amplifiers 141 and 142 is an amplifier circuit that includes an operational amplifier or the like and that amplifies an inputted electrical signal. The first amplifier 141 amplifies the microwave signal E_{MW} inputted from the signal generator 140 and outputs an amplified microwave signal E_{A_WM}. The second amplifier 142 amplifies the radio wave signal E_{RF} inputted from the signal generator 140 and outputs an amplified radio wave signal E_{A_RF}. The first and second antennas 143 and 144 are formed of copper wires, and, in response to input of an electrical signal having a predetermined wavelength, irradiate the diamond 17 with a radio wave having the wavelength of the inputted electrical signal. In response to input of the amplified microwave signal E_{A_WM}, the first antenna 143 irradiates the diamond 17 with a microwave MW having the microwave wavelength of the inputted amplified microwave signal E_{A_WM}. In response to input of the amplified radio wave signal E_{A_RF}, the second antenna 144 irradiates the diamond 17 with a radio wave RF having the radio wave wavelength of the inputted amplified radio wave signal E_{A_RF}.

The microwaves MW with which the diamond 17 is irradiated include a first microwave MW1 having a wavelength of 0.10816 m and a second microwave MW2 having a wavelength of 0.10799 m when a static magnetic field B of 60 gauss is applied at an angle of 52° with respect to the direction of nitrogen-vacancy alignment in the NV centers. The wavelength of the first microwave MW1 is also referred to as a first microwave wavelength, and that of the second microwave MW2 as a second microwave wavelength. The radio waves RF with which the diamond 17 is irradiated include a first radio wave RF1 having a wavelength of 41.748 m and a second radio wave RF2 having a wavelength of 105.45 m when a static magnetic field B of 60 gauss is applied at an angle of 52° with respect to the direction of nitrogen-vacancy alignment in the NV centers. The wavelength of the first radio wave RF1 is also referred to as a first radio wave wavelength, and that of the second radio wave RF2 as a second radio wave wavelength.

The static magnetic field application device 15 is a current source that supplies an excitation current I_{B} to the coil 16. The coil 16 is formed of a conductive linear member such as a copper wire and is wound around the diamond 17. In response to the supply of an excitation current I_{B} from the static magnetic field application device 15, the coil 16 applies a static magnetic field corresponding to the excitation current I_{B}, i.e., a transverse magnetic field, to the diamond 17. Although the apparatus 1 includes a static magnetic field application device 15 and a coil 16, the apparatus for polarizing nuclear spins of the embodiment may include a permanent magnet that applies a transverse magnetic field to the diamond 17, instead of the static magnetic field application device 15 and the coil 16.

The diamond 17 has a rectangular parallelepiped shape and includes multiple NV centers 17a. In response to irradiation with a microwave MW from the wave irradiation device 14, the energy levels mₛ of electron spins of each NV center 17a transition from mₛ=0 to mₛ=−1. At irradiation with a first microwave MW1, the energy levels mₛ of electron spins of each NV center 17a of which the energy level mₗ of the nuclear spin is mₗ=1 transition from mₛ=0 to mₛ=−1. At irradiation with a second microwave MW2, the energy levels mₛ of electron spins of each NV center 17a of which the energy level mₗ of the nuclear spin is mₗ=−1 transition from mₛ=0 to mₛ=−1.

In response to irradiation with a radio wave RF from the wave irradiation device 14, the energy level mₗ of the nuclear spin of each NV center 17a transitions from mₗ=1 or m=−1 to mₗ=0. At irradiation with a first radio wave RF1, the energy level mₗ of the nuclear spin of each NV center 17a of which the energy levels mₛ of electron spins are mₛ=−1 transitions from mₗ=1 to mₗ=0. At irradiation with a second radio wave RF2, the energy level mₗ of the nuclear spin of each NV center 17a of which the energy levels mₛ of electron spins are mₛ=−1 transitions from mₗ=−1 to mₗ=0.

In response to irradiation with laser light L1 from the light source 10, the energy levels mₛ of electron spins of each NV center 17a transition from mₛ=−1 to mₛ=0.

The controller 20 includes a communication unit 21, a storage unit 22, an operation unit 23, a display unit 24, and a processing unit 25, and is a mobile device such as a smartphone or a computer such as a personal computer or a server and executes a method for polarizing nuclear spins of the embodiment.

The communication unit 21 includes a communication interface circuit for connecting the controller 20 to the light source 10, the photoelectric conversion element 13, the wave irradiation device 14, the static magnetic field application device 15, and an external device (not shown) via a network (not shown). The communication unit 21 provides data received via the network from the light source 10, the photoelectric conversion element 13, the wave irradiation device 14, the static magnetic field application device 15, and the external device (not shown) to the processing unit 25. The communication unit 21 also transmits data provided from the processing unit 25 to the light source 10, the photoelectric conversion element 13, the wave irradiation device 14, the static magnetic field application device 15, and the external device (not shown) via the network.

The storage unit 22 includes, for example, one of a semiconductor memory, a magnetic disk drive, and an optical disk drive, and stores an operating system program, driver programs, application programs, and other data used for processing by the processing unit 25. For example, as driver programs, the storage unit 22 stores an input device driver program for controlling the operation unit 23 and an output device driver program for controlling the display unit 24. The storage unit 22 stores a program for polarizing nuclear spins that causes the processing unit 25 to execute a process for polarizing nuclear spins, and also stores various types of data and information used for the process for polarizing nuclear spins.

The operation unit 23 may be any device that can operate the controller 20, such as a keyboard or a touch pad. An operator can input letters, numerals, or the like via the operating unit 23. When operated by an operator, the operation unit 23 generates a signal corresponding to the operation. The generated signal is provided to the processing unit 25 as an operator instruction.

The display unit 24 may be any device that can display video, images, text, or the like, such as a liquid crystal display or an organic electroluminescent (EL) display. The display unit 24 displays video, images, text, or the like corresponding to video data, image data, or text data provided from the processing unit 25. The display unit 24 may also display a graphical user interface (GUI) for operating the controller 20.

The processing unit 25 includes one or more processors and their peripheral circuits. The processing unit 25 centrally controls the overall operation of the controller 20, and is, for example, a CPU. The processing unit 25 controls the operation of the communication unit 21, the display unit 24, and the like so that various types of processing of the controller 20 are executed in appropriate procedures according to the programs stored in the storage unit 22, the operation of the operation unit 23, and the like. The processing unit 25 executes processing based on the programs stored in the storage unit 22 (e.g., the operating system program, driver programs, and application programs). The processing unit 25 can execute multiple programs (e.g., application programs) in parallel.

The processing unit 25 includes a static magnetic field control unit 26, a laser control unit 27, and a wave control unit 28. These units are functional modules implemented by a program executed by the processor included in the processing unit 25, or may be implemented in the controller 20 as firmware.

### (Process for Polarizing Nuclear Spins of the Embodiment)

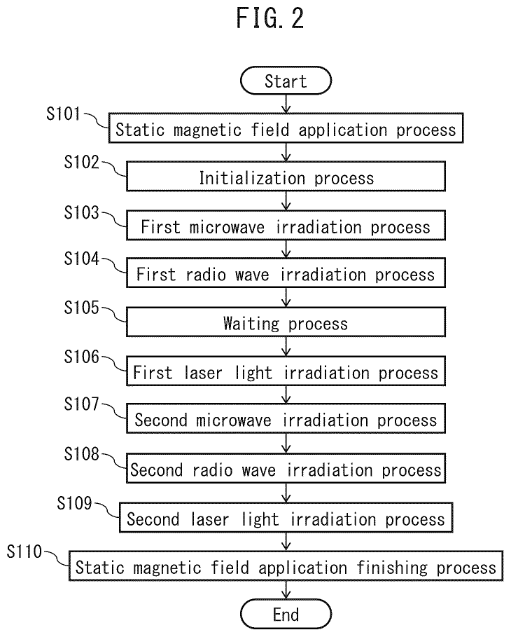

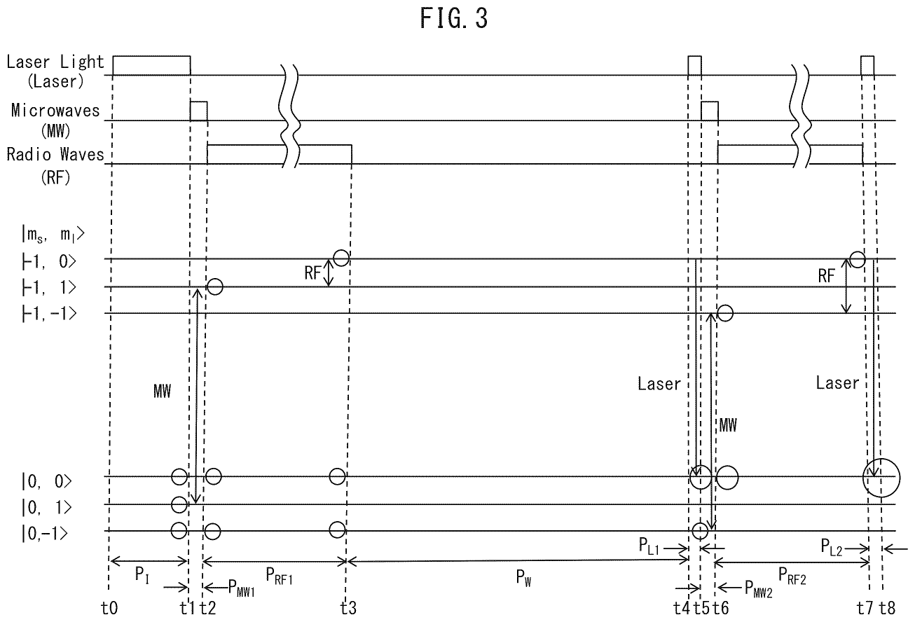

FIG. 2 is a flowchart showing a process for polarizing nuclear spins including a method for polarizing nuclear spins executed by the processing unit 25. FIG. 3 is a timing chart of the process for polarizing nuclear spins shown in FIG. 2. The process for polarizing nuclear spins shown in FIGS. 2 and 3 is executed mainly by the processing unit 25 in cooperation with the components of the apparatus 1, based on the program for polarizing nuclear spins pre-stored in the storage unit 22. The process for polarizing nuclear spins shown in FIGS. 2 and 3 is executed for one of the NV centers 17a included in the diamond 17.

First, the static magnetic field control unit 26 executes a static magnetic field application process (S101). To the static magnetic field application device 15, the static magnetic field control unit 26 outputs a static magnetic field application signal indicating the application of a static magnetic field to the diamond 17. In response to input of a static magnetic field application signal, the static magnetic field application device 15 starts supplying an excitation current I_{B} to the coil 16. In response to the supply of an excitation current I_{B}, the coil 16 applies a static magnetic field to the diamond 17.

Next, in an initialization period PI between time t0 and t1, the laser control unit 27 executes an initialization process to irradiate multiple NV centers 17a with laser light L1 to transition the energy levels mₛ of electron spins of the NV centers 17a to mₛ=0 (S102). To the light source 10, the laser control unit 27 outputs an initialization laser light irradiation signal indicating the irradiation of the diamond 17 with laser light L1. In response to input of an initialization laser light irradiation signal, the light source 10 irradiates the diamond 17 with laser light L1 for the initialization period PI, e.g., 4 μs. The irradiation of the NV centers 17a included in the diamond 17 with laser light L1 for the initialization period PI transitions the energy levels mₛ of electron spins of the NV centers 17a to mₛ=0. The initialization process causes the nuclear spins to have energy levels mₗ of 0 and ±1 substantially equally.

Next, the wave control unit 28 executes a first microwave irradiation process in a first microwave irradiation period P_{MW1} between time t1 and t2 (S103). In the first microwave irradiation process, the wave control unit 28 irradiates the NV centers 17a with a first microwave MW1 to transition the energy levels mₛ of electron spins of the NV centers 17a from mₛ=0 to mₛ=−1. To the signal generator 140 of the wave irradiation device 14, the wave control unit 28 outputs a first microwave irradiation signal indicating the irradiation of the diamond 17 with a first microwave MW1. In response to input of a first microwave irradiation signal, the signal generator 140 irradiates the diamond 17 with a first microwave MW1 via the first amplifier 141 and the first antenna 143 for the first microwave irradiation period P_{MW1}, e.g., 500 ns. The irradiation with a first microwave MW1 transitions the energy levels mₛ of electron spins of the NV centers 17a in the diamond 17 of which the energy levels mₗ of nuclear spins are mₗ=1 from mₛ=0 to mₛ=−1. The first microwave irradiation process causes the energy levels mₛ of electron spins of the NV centers 17a of which the energy levels mₗ of nuclear spins are mₗ=1 to transition from mₛ=0 to mₛ=−1.

Next, the wave control unit 28 executes a first radio wave irradiation process in a first radio wave irradiation period P_{RF1} between time t2 and t3 (S104). In the first radio wave irradiation process, the wave control unit 28 irradiates the NV centers 17a with a first radio wave RF1 to transition the energy levels mₗ of nuclear spins of the NV centers 17a to mₗ=0. To the signal generator 140, the wave control unit 28 outputs a first radio wave irradiation signal indicating the irradiation of the diamond 17 with a first radio wave RF1. In response to input of a first radio wave irradiation signal, the signal generator 140 irradiates the diamond 17 with a first radio wave RF1 via the second amplifier 142 and the second antenna 144 for the first radio wave irradiation period P_{RF1}, e.g., 43 μs. The irradiation with a first radio wave RF1 transitions the energy levels mₗ of nuclear spins of the NV centers 17a in the diamond 17 of which the energy levels mₛ of electron spins are mₛ=−1 from mₗ=1 to mₗ=0. The first radio wave irradiation process causes the energy levels mₗ of nuclear spins of the NV centers 17a of which the energy levels mₛ of electron spins are mₛ=−1 to transition from mₗ=1 to mₗ=0.

Next, the laser control unit 27 executes a waiting process to wait to execute a first laser light irradiation process for a laser light irradiation waiting period Pw between time t3 and t4 (S105). The laser control unit 27 executes a timing process until the time elapsed since the end of the first microwave irradiation process reaches the laser light irradiation waiting period P_{W}, and waits to execute a first laser light irradiation process during the timing process.

The laser light irradiation waiting period Pw is a period obtained by subtracting the first radio wave irradiation period P_{RF1} and a first laser light irradiation period P_{L1} from a microwave irradiation waiting period determined from the period of the mixed state of nuclear spins given by expression (15). The microwave irradiation waiting period is the period between the end time of the first microwave irradiation process, time t2, and the start time of a second microwave irradiation process, time t5. The microwave irradiation waiting period only has to be an integer multiple of the period of the mixed state of nuclear spins given by expression (15), and is, for example, equal to the period of the mixed state of nuclear spins.

Next, the laser control unit 27 executes a first laser light irradiation process in a first laser light irradiation period P_{L1} between time t4 and t5 (S106). In the first laser light irradiation process, the laser control unit 27 irradiates the NV centers 17a subjected to the first radio wave irradiation process indicated by S104 with laser light L1 to transition the energy levels mₛ of electron spins from mₛ=−1 to mₛ=0. To the light source 10, the laser control unit 27 outputs a first laser light irradiation signal indicating the irradiation of the diamond 17 with laser light L1. In response to input of a first laser light irradiation signal, the light source 10 irradiates the diamond 17 with laser light L1 for the first laser light irradiation period P_{L1}, e.g., 300 ns. The irradiation of the NV centers 17a included in the diamond 17 with laser light L1 for the first laser light irradiation period P_{L1} transitions the energy levels mₛ of electron spins from mₛ=−1 to mₛ=0 with the energy levels mₗ of nuclear spins transitioned to mₗ=0. The first laser light irradiation process causes the energy levels mₛ of electron spins of the NV centers 17a of which the energy levels mₗ of nuclear spins are mₗ=0 to transition from mₛ=−1 to mₛ=0.

Next, the wave control unit 28 executes a second microwave irradiation process in a second microwave irradiation period P_{MW2} between time t5 and t6 (S107). In the second microwave irradiation process, the wave control unit 28 irradiates the NV centers 17a with a second microwave MW2 having a second microwave wavelength to transition the energy levels mₛ of electron spins of the NV centers 17a from mₛ=0 to mₛ=−1. To the signal generator 140, the wave control unit 28 outputs a second microwave irradiation signal indicating the irradiation of the diamond 17 with a second microwave MW2. In response to input of a second microwave irradiation signal, the signal generator 140 irradiates the diamond 17 with a second microwave MW2 via the first amplifier 141 and the first antenna 143 for the second microwave irradiation period PMW2, e.g., 500 ns. The irradiation with a second microwave MW2 transitions the energy levels mₛ of electron spins of the NV centers 17a in the diamond 17 of which the energy levels mₗ of nuclear spins are mₗ=−1 from mₛ=0 to mₛ=−1. The second microwave irradiation process causes the energy levels mₛ of electron spins of the NV centers 17a of which the energy levels mₗ of nuclear spins are mₗ=−1 to transition from mₛ=0 to mₛ=−1.

Next, the wave control unit 28 executes a second radio wave irradiation process in a second radio wave irradiation period P_{RF2} between time t6 and t7 (S108). In the second radio wave irradiation process, the wave control unit 28 irradiates the NV centers 17a with a second radio wave RF2 having a second radio wave wavelength to transition the energy levels mₗ of nuclear spins of the NV centers 17a to mₗ=0. To the signal generator 140, the wave control unit 28 outputs a second radio wave irradiation signal indicating the irradiation of the diamond 17 with a second radio wave RF2. In response to input of a second radio wave irradiation signal, the signal generator 140 irradiates the diamond 17 with a second radio wave RF2 via the second amplifier 142 and the second antenna 144 for the second radio wave irradiation period P_{RF2}, e.g., 43 μs. The irradiation with a second radio wave RF2 transitions the energy levels mₗ of nuclear spins of the NV centers 17a in the diamond 17 of which the energy levels mₛ of electron spins are mₛ=−1 from mₗ=−1 to mₗ=0. The second radio wave irradiation process causes the energy levels mₗ of nuclear spins of the NV centers 17a of which the energy levels mₛ of electron spins are mₛ=−1 to transition from mₗ=−1 to mₗ=0.

Next, the laser control unit 27 executes a second laser light irradiation process in a second laser light irradiation period P_{L2} between time t7 and t8 (S109). The laser control unit 27 irradiates the NV centers 17a subjected to the second radio wave irradiation process indicated by S108 with laser light L1 to transition the energy levels mₛ of electron spins from mₛ=−1 to mₛ=0. To the light source 10, the laser control unit 27 outputs a second laser light irradiation signal indicating the irradiation of the diamond 17 with laser light L1. In response to input of a second laser light irradiation signal, the light source 10 irradiates the diamond 17 with laser light L1 for the second laser light irradiation period P_{L2}, e.g., 300 ns. The irradiation of the NV centers 17a included in the diamond 17 with laser light L1 for the second laser light irradiation period P_{L2} transitions the energy levels mₛ of electron spins from mₛ=−1 to mₛ=0 with the energy levels mₗ of nuclear spins transitioned to mₗ=0. The second laser light irradiation process causes the energy levels mₛ of electron spins of the NV centers 17a of which the energy levels mₗ of nuclear spins are mₗ=0 to transition from mₛ=−1 to mₛ=0.

The static magnetic field control unit 26 then executes a static magnetic field application finishing process to finish applying a static magnetic field (S110). To the static magnetic field application device 15, the static magnetic field control unit 26 outputs a static magnetic field application end signal indicating the end of application of a static magnetic field to the diamond 17. In response to input of a static magnetic field application end signal, the static magnetic field application device 15 finishes supplying an excitation current I_{B} to the coil 16. In response to the end of supply of an excitation current I_{B}, the coil 16 finishes applying a static magnetic field to the diamond 17.

### (Operational Advantages of the Apparatus for Polarizing Nuclear Spins of the Embodiment)

The apparatus 1 executes the second radio wave irradiation process when a microwave irradiation waiting period determined depending on the period given by expression (15) has elapsed since execution of the first microwave irradiation process, and thus can execute the second radio wave irradiation process with the nuclear spins polarized. Executing the second radio wave irradiation process with the nuclear spins polarized enables the apparatus 1 to prevent reduction in the fidelity of polarization of nuclear spins and to improve the fidelity of quantum manipulation of electron spins.

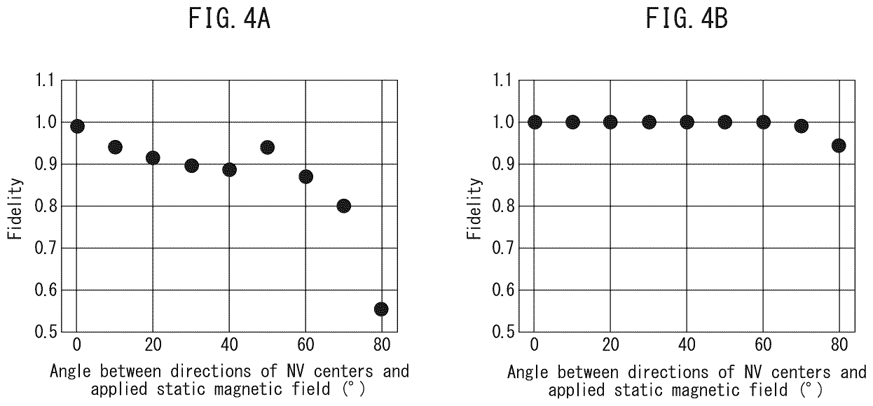

FIG. 4A shows how the fidelity of quantum manipulation of nuclear spins depends on the direction of an applied static magnetic field in a method for polarizing nuclear spins of a comparative example. FIG. 4B shows how the fidelity of quantum manipulation of nuclear spins depends on the direction of an applied static magnetic field in the method for polarizing nuclear spins of the embodiment. In FIGS. 4A and 4B, the abscissa represents the angle between the directions of nitrogen-vacancy alignment in NV centers and an applied static magnetic field, and the ordinate represents the fidelity of quantum manipulation of nuclear spins.

In the method for polarizing nuclear spins of the comparative example, the first radio wave irradiation process and the first laser light irradiation process are executed successively without a laser light irradiation waiting period. The method for polarizing nuclear spins of the embodiment includes a waiting process to wait to execute the first laser light irradiation process for a laser light irradiation waiting period determined depending on the microwave irradiation waiting period, between the first radio wave irradiation process and the first laser light irradiation process.

The fidelities F of quantum manipulation of nuclear spins shown in FIGS. 4A and 4B are calculated using expressions (16) and (17), respectively. In expressions (16) and (17), P(•) denotes the probability that an electron exists in • state, and g denotes the ground state. The static magnetic field B applied to the NV centers is given by (sin θ·6.1 mT, 0, cos θ·6.1 mT). θ is the angle (°) between the directions of nitrogen-vacancy alignment in the NV centers and the applied static magnetic field, and is calculated in 10° increments from 0° to 80°. The irradiation time of radio waves is 105.9 μs; the power of the radio waves is πγ_{N}/(φ105.9×10⁶γ_{N}) W; the initial state is given by expression (18).

$$[ Expression 10 ]$$

$$F = \frac{P ( g , - 1 , 0 ) + P ( g , + , 0 )}{P ( g , - 1 , - 1 ) + P ( g , + 1 , + 1 )} \qquad ( 16 )$$

$$[ Expression 11 ]$$

$$F = \frac{P ( g , - 1 , 0 )}{P ( g , - 1 , - 1 )} \qquad ( 17 )$$

$$[ Expression 12 ]$$

$$ρ \text{?} = \frac{1}{3} ( \text{?} g , - 1 , + 1 \text{?} ( g , - 1 , + 1 \text{?} + \text{?} g , 0 , 0 \text{?} \text{?} g , 0 , 0 \text{?} + \text{?} g , 0 , + 1 \text{?} \text{?} g , 0 , + 1 \text{?} ) \qquad ( 18 )$$

$$\text{?} \text{indicates text missing or illegible when filed}$$

In the method for polarizing nuclear spins of the comparative example, the fidelity F gradually decreases from 100% as the angle between the directions of nitrogen-vacancy alignment in the NV centers and the applied static magnetic field increases, as shown in FIG. 4A. In the method for polarizing nuclear spins of the comparative example, the fidelity F decreases to about 55% when the angle between the directions of nitrogen-vacancy alignment in the NV centers and the applied static magnetic field reaches 80°.

In the method for polarizing nuclear spins of the embodiment, the fidelity F is maintained at approximately 100% even when the angle between the directions of nitrogen-vacancy alignment in the NV centers and the applied static magnetic field increases from 0° to 60°, as shown in FIG. 4B. In the method for polarizing nuclear spins of the embodiment, the fidelity F remains at about 98% even when the angle between the directions of nitrogen-vacancy alignment in the NV centers and the applied static magnetic field is 70°. In the method for polarizing nuclear spins of the embodiment, the fidelity F decreases only to about 95% even when the angle between the directions of nitrogen-vacancy alignment in the NV centers and the applied static magnetic field reaches 80°. In the method for polarizing nuclear spins of the embodiment, the laser light irradiation waiting period between the first radio wave irradiation process and the first laser light irradiation process increases the fidelity of quantum manipulation of nuclear spins, regardless of the discrepancy between the directions of nitrogen-vacancy alignment in the NV centers and the applied static magnetic field.

The apparatus 1 executes the first microwave irradiation process, and then the first radio wave irradiation process and the first laser light irradiation process, enabling the energy levels mₗ of nuclear spins to be polarized to mₗ=0 when the energy levels mₛ of electron spins are mₛ=0.

The apparatus 1 executes the second microwave irradiation process, and then the second radio wave irradiation process and the second laser light irradiation process, enabling the energy levels mₗ of nuclear spins to be further polarized to mₗ=0 when the energy levels mₛ of electron spins are mₛ=0.

The apparatus 1 executes the process for polarizing nuclear spins that further includes a waiting process to wait to execute the first laser light irradiation process for a laser light irradiation waiting period determined depending on the microwave irradiation waiting period, between the first radio wave irradiation process and the first laser light irradiation process. The apparatus 1 can execute the first laser light irradiation process and the second microwave irradiation process successively by executing the process for polarizing nuclear spins including the waiting process.

By setting the laser light irradiation waiting period Pw to the order of microseconds, the apparatus 1 can execute the second microwave irradiation process after the microwave irradiation waiting period, which is on the order of microseconds, has elapsed since the first microwave irradiation process. By setting the laser light irradiation waiting period Pw to be longer than 10 μs, the apparatus 1 can execute the second microwave irradiation process after the microwave irradiation waiting period, which is on the order of microseconds, has elapsed since the first microwave irradiation process.

### (Modified Examples of the Apparatus for Polarizing Nuclear Spins of the Embodiment)

In the first microwave irradiation process, the apparatus 1 transitions the energy levels mₛ of electron spins of the NV centers 17a of which the energy levels mₗ of nuclear spins are mₗ=1 from mₛ=0 to mₛ=−1. However, in the first microwave irradiation process, the apparatus for polarizing nuclear spins of the embodiment may transition the energy levels mₛ of electron spins of the NV centers 17a of which the energy levels mₗ of nuclear spins are one of mₗ=1 or −1 from mₛ=0 to mₛ=−1. In the second microwave irradiation process, the apparatus for polarizing nuclear spins of the embodiment transitions the energy levels mₛ of electron spins of the NV centers 17a of which the energy levels mₗ of nuclear spins are the other of mₗ=1 or −1.

In the first microwave irradiation process, an apparatus for polarizing nuclear spins of a modified example transitions the energy levels mₛ of electron spins of NV centers of which the energy levels mₗ of nuclear spins are mₗ=−1 from mₛ=0 to mₛ=−1. In the second microwave irradiation process, the apparatus for polarizing nuclear spins of the modified example transitions the energy levels mₛ of electron spins of the NV centers of which the energy levels mₗ of nuclear spins are mₗ=1 from mₛ=0 to mₛ=−1.

In the first radio wave irradiation process, the apparatus for polarizing nuclear spins of the modified example transitions the energy levels mₗ of nuclear spins of the NV centers of which the energy levels mₛ of electron spins are mₛ=−1 from mₗ=−1 to mₗ=0. In the second radio wave irradiation process, the apparatus for polarizing nuclear spins of the modified example transitions the energy levels mₗ of nuclear spins of the NV centers of which the energy levels mₛ of electron spins are mₛ=−1 from mₗ=1 to mₗ=0.

The apparatus for polarizing nuclear spins executes the initialization process before the first microwave irradiation process; however, the apparatus for polarizing nuclear spins of the embodiment need not necessarily execute the initialization process before the first microwave irradiation process.

What is claimed is:

1. A method for polarizing nuclear spins, comprising:
a static magnetic field application process to apply a static magnetic field to NV centers;
a first microwave irradiation process to irradiate the NV centers with a microwave having a first microwave wavelength to transition energy levels mₛ of electron spins of the NV centers of which energy levels mₗ of nuclear spins are one of mₗ=1 or −1 from mₛ=0 to mₛ=−1; and
a second microwave irradiation process to irradiate the NV centers with a microwave having a second microwave wavelength different from the first microwave wavelength to transition the energy levels mₛ of electron spins of the NV centers of which the energy levels mₗ of the nuclear spins are the other of mₗ=1 or −1 from mₛ=0 to mₛ=−1 when a microwave irradiation waiting period determined depending on the period of state mixing of polarization of the nuclear spins has elapsed since execution of the first microwave irradiation process.

2. The method according to claim 1, wherein the first microwave irradiation process causes the energy levels mₛ of the electron spins of the NV centers of which the energy levels mₗ of the nuclear spins are mₗ=1 to transition from mₛ=0 to mₛ=−1, and
the second microwave irradiation process causes the energy levels mₛ of the electron spins of the NV centers of which the energy levels mₗ of the nuclear spins are mₗ=−1 to transition from mₛ=0 to mₛ=−1.

3. The method according to claim 1, wherein the first microwave irradiation process causes the energy levels mₛ of the electron spins of the NV centers of which the energy levels mₗ of the nuclear spins are mₗ=−1 to transition from mₛ=0 to mₛ=−1, and
the second microwave irradiation process causes the energy levels mₛ of the electron spins of the NV centers of which the energy levels mₗ of the nuclear spins are mₗ=1 to transition from mₛ=0 to mₛ=−1.

4. The method according to claim 1, further comprising:
a first radio wave irradiation process to irradiate the NV centers subjected to the first microwave irradiation process with a radio wave having a first radio wave wavelength to transition the energy levels mₗ of the nuclear spins to mₗ=0 with the energy levels mₛ of the electron spins transitioned to mₛ=−1; and
a first laser light irradiation process to irradiate the NV centers subjected to the first radio wave irradiation process with laser light having a laser light wavelength to transition the energy levels mₛ of the electron spins from mₛ=−1 to mₛ=0 with the energy levels mₗ of the nuclear spins transitioned to mₗ=0.

5. The method according to claim 4, further comprising:
a second radio wave irradiation process to irradiate the NV centers subjected to the second microwave irradiation process with a radio wave having a second radio wave wavelength different from the first radio wave wavelength to transition the energy levels mₗ of the nuclear spins to mₗ=0 with the energy levels mₛ of the electron spins transitioned to mₛ=−1; and
a second laser light irradiation process to irradiate the NV centers subjected to the second radio wave irradiation process with the laser light to transition the energy levels mₛ of the electron spins from mₛ=−1 to mₛ=0 with the energy levels mₗ of the nuclear spins transitioned to mₗ=0.

6. The method according to claim 5, further comprising an initialization process to irradiate the NV centers with the laser light to transition the energy levels mₛ of the electron spins of the NV centers to mₛ=0 before the first microwave irradiation process.

7. The method according to claim 6, further comprising a waiting process to wait to execute the first laser light irradiation process for a laser light irradiation waiting period determined depending on the microwave irradiation waiting period, between the first radio wave irradiation process and the first laser light irradiation process.

8. The method according to claim 7, wherein the laser light irradiation waiting period is on the order of microseconds.

9. The method according to claim 8, wherein the laser light irradiation waiting period is longer than 10 μs.

10. A non-transitory storage medium storing a program for polarizing nuclear spins, the program causing a computer to execute a process comprising:
a static magnetic field application process to apply a static magnetic field to NV centers;
a first microwave irradiation process to irradiate the NV centers with a microwave having a first microwave wavelength to transition energy levels mₛ of electron spins of the NV centers of which energy levels mₗ of nuclear spins are one of mₗ=1 or −1 from mₛ=0 to mₛ=−1; and
a second microwave irradiation process to irradiate the NV centers with a microwave having a second microwave wavelength different from the first microwave wavelength to transition the energy levels mₛ of electron spins of the NV centers of which the energy levels mₗ of the nuclear spins are the other of mₗ=1 or −1 from mₛ=0 to mₛ=−1 when a microwave irradiation waiting period determined depending on the period of state mixing of polarization of the nuclear spins has elapsed since execution of the first microwave irradiation process.

11. An apparatus for polarizing nuclear spins, comprising:
a diamond with NV centers formed;
a static magnetic field application device configured to apply a static magnetic field to the NV centers;
a wave irradiation device configured to irradiate the NV centers with radio waves; and
a controller configured to control the static magnetic field application device and the wave irradiation device,
the controller being configured to execute
a static magnetic field application process for the static magnetic field application device to apply the static magnetic field to the NV centers;
a first microwave irradiation process for the wave irradiation device to irradiate the NV centers with a microwave having a first microwave wavelength to transition energy levels mₛ of electron spins of the NV centers of which energy levels mₗ of nuclear spins are one of mₗ=1 or −1 from mₛ=0 to mₛ=−1; and
a second microwave irradiation process for the wave irradiation device to irradiate the NV centers with a microwave having a second microwave wavelength different from the first microwave wavelength to transition the energy levels mₛ of electron spins of the NV centers of which the energy levels mₗ of the nuclear spins are the other of mₗ=1 or −1 from mₛ=0 to mₛ=−1 when a microwave irradiation waiting period determined depending on the period of state mixing of polarization of the nuclear spins has elapsed since execution of the first microwave irradiation process.
